(19) United States
(12) Patent Application Publication
(10) Pub. No.: US 2002/0126301 A1
(43) Pub. Date: Sep. 12, 2002

(54) Self calibrating ink jet cartridges

(76) Inventor: Harry Bowers, Pouqhquag, NY (US)

Correspondence Address: CALFEE HALTER & GRISWOLD, LLP, 800 SUPERIOR AVENUE, SUITE 1400, CLEVELAND, OH, 44114, US

(21) Appl. No.: 10/037,138

(22) Filed: Dec. 21, 2001

Related U.S. Application Data
(60) Provisional application No. 60/257,239, filed on Dec. 21, 2000.

(51) Int. Cl. B41J 1/00; G06F 15/00; G03F 3/08

(52) U.S. Cl. 358/1.9; 358/504; 358/518

(57) ABSTRACT

A method of providing calibration data to a printer to achieve a true color value. An ink cartridge with a memory for storing tristimulus values measured from selected printers and from selected print substrate used to compute a color adjustment value to correct the output color data to equal the input color data.

### CROSS REFERENCE TO RELATED APPLICATIONS

This application claims the benefit of U.S. Provisional Application No. 60/257,239 filed on Dec. 21, 2000, the disclosure of which is incorporated by reference herein.

### FIELD OF THE INVENTION

The present invention relates to printer cartridges and color calibration. Particularly, the invention calibrates a printer based on color data from a cartridge.

### BACKGROUND

Prior art shows that memory for an ink cartridge already has the capability to measure the level of ink remaining in the cartridge. However, the cartridge cannot measure the value of the actual output color data from the printer.

Variation in color of inks are due to the difference in ink manufacturing from company to company. Due to these variations, the output color data of a printer is not equal to the input color data. In order to output the same color data values from a printer that is input to the printer, a calibration process would be necessary due to the ink color variables and inconsistencies.

To program the calibration process on to the memory of an ink cartridge, it would be necessary to measure the color inks for selected printers on different print substrate. The colors of ink can be measured by a spectrophotometer or a calorimeter. However, these measuring devices are extremely expensive for the average person. Therefore, it would be an advantage for a customer to purchase an ink cartridge with the color data already included in the memory of an ink cartridge to achieve the desired output color values.

### SUMMARY OF INVENTION

In accordance with the present invention, a method of providing calibration data to a printer is provided. A set of color patches from a predetermined set of input values are printed. Tristimulus values are measured from the color patches. Calibration data including tristimulus values is generated. The tristimulus values and the associated predetermined input values are stored in a memory embedded on an ink cartridge.

Still further advantages of the present invention will become apparent to those of ordinary skill in the art upon reading and understanding the following detailed description of the preferred embodiments.

### BRIEF DESCRIPTION OF DRAWINGS

The following is a brief description of each drawing used to describe the present invention, and thus, are being presented for illustrative purposes only and should not be limited to the scope of the present invention, wherein:

FIG. 1 is a process diagram of creating calibration data for an ink cartridge.

FIG. 2 shows one systematic diagram of the invention.

FIGS. 3A and 3B illustrate exemplary components for the invention.

FIG. 4 illustrates an exemplary decision process for a printer.

It will be appreciated that these processes and illustrations will be performed in different ways then illustrated. It will be further appreciated that other blocks can be combined with different blocks if desired.

### DETAILED DESCRIPTION

The invention will be described with reference to the Figures.

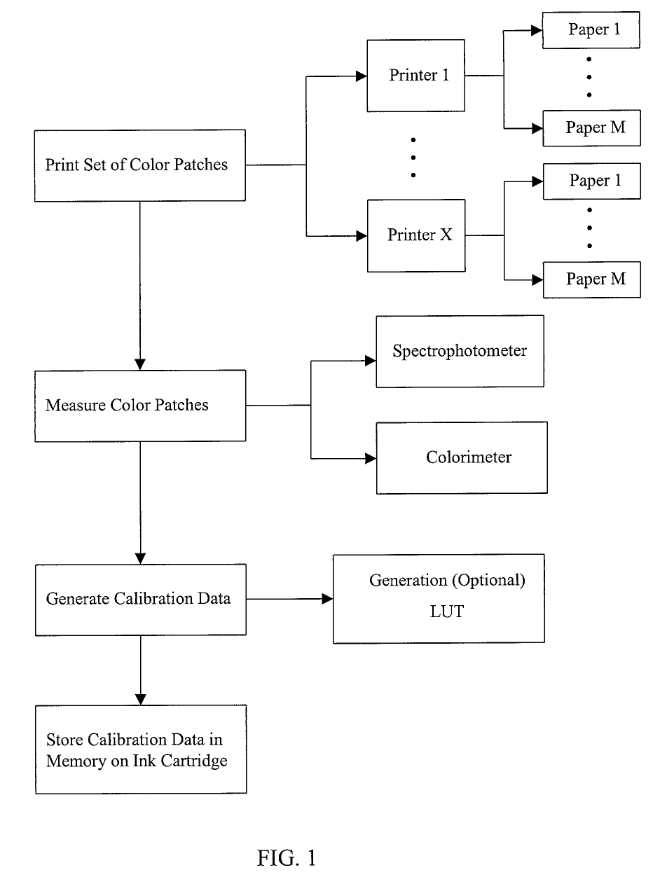

With reference to FIG. 1, a process for determining the color calibration for a selected printer and selected print substrate is shown. An initial set of color patches is printed from at least one printer and on at least one print substrate. The color value of ink will be different on each style and type of print substrate. Also, though an ink cartridge is adaptable to be installed with different printers, the print quality varies from printer to printer.

The printed color patches, having a predetermined input value, are measured for color values, such as tristimulus values. Most often, either a spectrophotometer or a calorimeter will be the device used to measure the color values from the set of color patches.

The creation of a look-up table (LUT) is optional. The input and measured color values, or raw data, are used to generate calibration data. The LUT stores a difference value or an adjusted value between the predetermined input values and the measured color value. The calibration data may be either or both the raw data and the adjusted value. The calibration data is stored preferably on a memory embedded in an ink cartridge. The LUT may also be stored on the memory, however, an LUT needs a large size of memory space. Therefore, it is advantageous to store only the raw data on the memory and create the LUT just before printing.

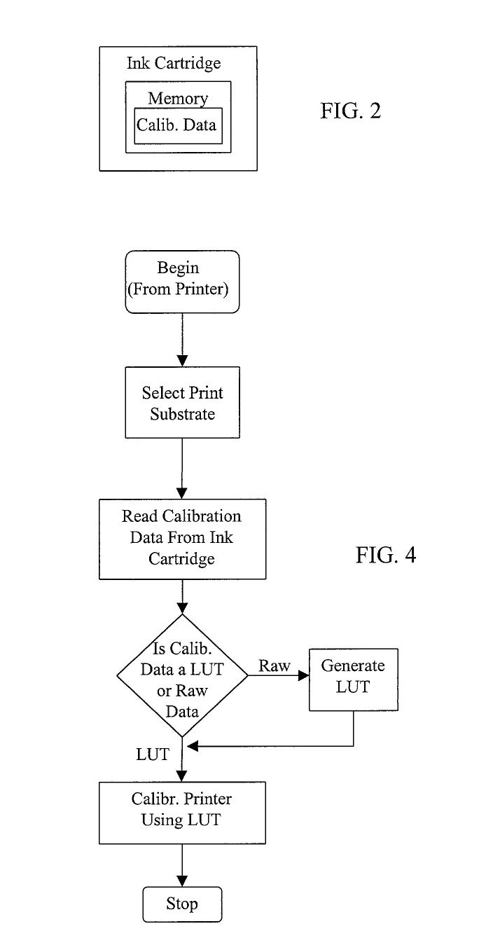

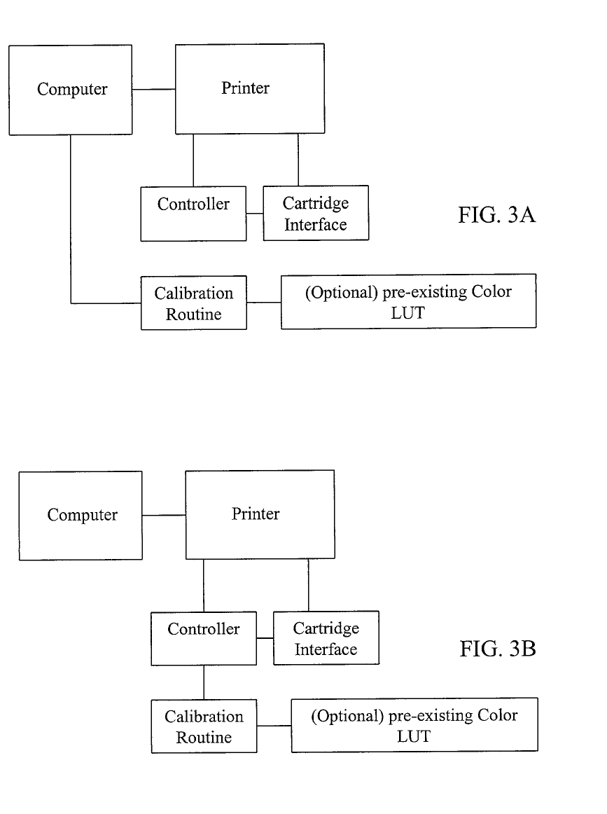

In reference to FIGS. 3A and 3B, a systematic diagram shows one relationship between the color calibration components. The finished product of the process illustrated in Figure, which is the calibration data in the memory embedded on the ink cartridge shown in FIG. 2, interfaces with a printer. The printer has a controller and is connected to a computer. As shown in FIG. 3A, the calibration routine of finding the adjusted values and an optional pre-existing color LUT are stored in the computer. An alternative component relationship may have the calibration routine and the optional pre-existing color LUT stored with the controller of the printer shown in FIG. 3B. If a color LUT does not exist, then one is generated with the process shown in FIG. 1. This pre-existing color LUT may be replaced, modified, or updated with the new color LUT generated in FIG. 1. Also, an adjustment value may be added to the pre-existing color LUT.

In reference to FIG. 4, the decision process the printer steps through during operation and after input data has been sent to the printer is shown. The printer will read the calibration data from the ink cartridge. If the calibration data is raw data, such as the predetermined input values and the measured color values, then the printer will have a color LUT generated. If the calibration data comprises of a color LUT with adjusted color values, then the printer will immediately begin the calibration process of adjusting the output color value to be equal to the input color value.

Although the invention has been described in detail with reference to certain preferred embodiments thereof, other embodiments are possible. Therefore, the spirit and scope of the appended claims should not be limited to the description of the preferred embodiment contained herein.

I claim:

1. A method of providing calibration data to a printer comprising the steps of:
printing a set of color patches from a predetermined set of input values;
measuring color values of said color patches;
generating calibration data including color values; and
storing, in a memory embedded on an ink cartridge, said color values and the associated said predetermined input values.

2. The method of claim 1 wherein printing said color patches are printed on a selected printer with a specific batch of ink.

3. The method of claim 1 further including printing said color patches on a plurality of print substrates and storing color calibration data for each of the plurality of print substrates.

4. The method of claim 1 wherein measuring said color values, such as tristimulus values, are measured with a spectrophotometer.

5. The method of claim 1 wherein measuring said color values, such as tristimulus values, are measured with a calorimeter.

6. The method of claim 1 wherein printing said set of color patches is from a predetermined set of color inks.

7. The method of claim 1 wherein generating said color calibration data comprises the step of determining a color adjustment look-up table with the difference value between said predetermined input values and said measured color values.

8. The method of claim 7 wherein determining said color adjustment look-up table is stored on said memory.

9. A method of reading color calibration data on a printer comprising the steps of:
reading color values stored on a memory of an ink cartridge; and
computing a color adjustment look-up table for specific ink cartridge and ink based on said color values.

10. The method according to claim 9 wherein computing said color adjustment look-up table determines the difference between a inputted color value in said printer and said stored color values.

11. A method of printing color data that has been calibrated from a select printer comprising the steps of:
selecting a print substrate;
reading calibration data stored on a memory of an ink cartridge for said selected print substrate;
computing a color adjustment look-up table based on said calibration data; and
calibrating by printing an adjusted color value that reflects an output color value equal to an input color value.

12. A method of printing color data that has been calibrated from a select printer comprising the steps of:
selecting a print substrate;
reading calibration data stored on a memory of an ink cartridge for said selected print substrate; and
calibrating by printing an adjusted color value that reflects an output color value equal to an input color value.

13. A device for calibrating a printer comprising of:
an ink cartridge; and
a memory embedded on said ink cartridge with stored color values.
